(19) United States
(12) Patent Application Publication
(10) Pub. No.: US 2025/0140738 A1
(43) Pub. Date: May 1, 2025

(54) SEMICONDUCTOR MANUFACTURING APPARATUS, METHOD OF MANUFACTURING SEMICONDUCTOR APPARATUS, AND SEMICONDUCTOR APPARATUS

(71) Applicant: Mitsubishi Electric Corporation, Tokyo (JP)

(72) Inventor: Takeru ZAIMA, Tokyo (JP)

(73) Assignee: Mitsubishi Electric Corporation, Tokyo (JP)

(21) Appl. No.: 18/735,435

(22) Filed: Jun. 6, 2024

(30) Foreign Application Priority Data
Oct. 25, 2023 (JP) 2023-183559

(51) Int. Cl. H01L 23/00; H01L 23/495

(52) U.S. Cl. CPC H01L 24/83; H01L 23/49513; H01L 24/32; H01L 24/75; H01L 2224/26175; H01L 2224/32245; H01L 2224/75611; H01L 2224/8385

(57) ABSTRACT

A nozzle of a semiconductor manufacturing apparatus includes a cross groove provided on a bottom surface, a supply hole provided in the center of the cross groove, and exhaust grooves that extend from ends of the cross groove to the outside of the bottom surface on the bottom surface and are shallower than the cross groove. The semiconductor manufacturing apparatus includes the nozzle, a syringe connected to the nozzle, and a dispenser that fills, in the cross groove, resin paste in the syringe via the supply hole with a gas pressure or an air pressure.

### BACKGROUND OF THE INVENTION

### Field

The present disclosure relates to a semiconductor manufacturing apparatus, a method of manufacturing a semiconductor apparatus, and a semiconductor apparatus.

### Background

JPH02-288241 A discloses a semiconductor manufacturing apparatus including a nozzle in which a cross groove is provided on a bottom surface. Resin paste has a cross shape immediately after discharge. The resin paste present in the center of a cross of the resin paste isotropically spreads. On the other hand, the resin paste present at ends of the cross hardly spreads and stays there. Therefore, as a result, the resin paste is spread in a quadrangular shape. A semiconductor device bonded in a later step is often a quadrangular shape in plan view. Therefore, the apparatus disclosed in JPH02-288241 A has an advantage that the apparatus can apply the resin paste along the shape of the semiconductor device to be bonded. When the resin paste is filled in the cross groove, air emitted from a dispenser escapes from the center of the cross groove in end directions. At this time, the resin paste that should be filled oozes from the ends of the cross groove to the outside together with the air. As a result, the spread resin paste has an unintended shape.

### SUMMARY

In order to solve the problem described above, a first object of the present disclosure is to provide a semiconductor manufacturing apparatus that makes it possible to spread resin paste in a quadrangular shape.

Further, a second object of the present disclosure is to provide a method of manufacturing a semiconductor apparatus that makes it possible to spread resin paste in a quadrangular shape.

Further, a third object of the present disclosure is to provide a semiconductor apparatus that makes it possible to spread resin paste in a quadrangular shape.

The features and advantages of the present disclosure may be summarized as follows.

According to an aspect of the present disclosure, a semiconductor manufacturing apparatus comprises a nozzle including a cross groove provided on a bottom surface, a supply hole provided in a center of the cross groove, and exhaust grooves that extend from ends of the cross groove to an outside of the bottom surface on the bottom surface and are shallower than the cross groove; a syringe configured to store resin paste and connected to the nozzle; and a dispenser configured to fill, in the cross groove, the resin paste in the syringe via the supply hole with a gas pressure or an air pressure.

According to an aspect of the present disclosure, a method of manufacturing a semiconductor apparatus comprises a step of bringing a bottom surface of a nozzle into contact with an application target object, the nozzle including a cross groove provided on the bottom surface, a supply hole provided in a center of the cross groove, and exhaust grooves that extend from ends of the cross groove to an outside of the bottom surface on the bottom surface and are shallower than the cross groove; a step of filling resin paste in the cross groove from the supply hole with a gas pressure or an air pressure; a step of separating the nozzle from the application target object and discharging the resin paste having a cross shape to the application target object; and a step of bonding a semiconductor device, which is a quadrangle in plan view, such that vertexes of the quadrangle and ends of a cross of the resin paste discharged in the cross shape coincide.

According to an aspect of the present disclosure, a method of manufacturing a semiconductor apparatus comprises a step of discharging resin paste to a range including a center of a cross-shaped block formed on a die pad and not including ends of the block; and a step of placing a semiconductor device, which is a quadrangle in plan view, on an upper surface of the block such that vertexes of the quadrangle and ends of a cross of the block coincide to bond the die pad and the semiconductor device with the resin paste.

According to an aspect of the present disclosure, a method of manufacturing a semiconductor apparatus comprises a step of forming a die pad including, on an upper surface, four grooves extending along respective sides of a quadrangle; a step of discharging resin paste to a range including a center of the quadrangle formed by the four grooves and not including the four grooves; and a step of placing a semiconductor device, which is a quadrangle in plan view, on the upper surface of the die pad such that vertexes of the quadrangle formed by the semiconductor device and vertexes of the quadrangle formed by the four grooves coincide to bond the die pad and the semiconductor device with the resin paste, wherein in plan view, the four grooves are present in centers of sides of the bonded semiconductor device and are absent at both ends of the sides of the semiconductor device.

According to an aspect of the present disclosure, a semiconductor apparatus comprises a die pad including a cross-shaped block on an upper surface; and a semiconductor device bonded to the block by resin paste, wherein the semiconductor device is a quadrangle in plan view and is bonded such that vertexes of the quadrangle of the semiconductor device and ends of a cross of the block coincide.

According to an aspect of the present disclosure, a semiconductor apparatus comprises a die pad; and a semiconductor device bonded to the die pad by resin paste, four sides of the semiconductor device forming a quadrangle in plan view, wherein the die pad includes, on a surface to which the semiconductor device is bonded, four grooves extending along the respective sides, and the grooves are present in centers of the sides in plan view and are absent at both ends of the sides.

Other and further objects, features and advantages of the invention will appear more fully from the following description.

### BRIEF DESCRIPTION OF DRAWINGS

FIG. 1 is a diagram illustrating a semiconductor manufacturing apparatus according to a first embodiment of the present disclosure.

FIG. 2 is a diagram illustrating the bottom surface of the tip of the nozzle according to the first embodiment of the present disclosure.

FIG. 3 is an A-A′ sectional view of the nozzle illustrated in FIG. 2.

FIG. 4 is a diagram illustrating the bottom surface of the nozzle of the semiconductor manufacturing apparatus according to a second embodiment of the present disclosure.

FIG. 5 is an A-A′ sectional view of the nozzle illustrated in FIG. 4.

FIG. 6 is a top view of a die pad according to a third embodiment of the present disclosure.

FIG. 7 is a side view of the die pad illustrated in FIG. 6.

FIG. 8 is a side view of a semiconductor apparatus according to the third embodiment of the present disclosure.

FIGS. 9 to 11 are diagrams illustrating a method of manufacturing the semiconductor apparatus according to the third embodiment of the present disclosure.

FIG. 12 is a top view of a die pad according to a fourth embodiment of the present disclosure.

FIG. 13 is an A-A′ sectional view of the die pad illustrated in FIG. 12.

FIG. 14 is a side view of a semiconductor apparatus according to the fourth embodiment of the present disclosure.

FIGS. 15 to 17 are diagrams illustrating a method of manufacturing the semiconductor apparatus according to the fourth embodiment of the present disclosure.

### DESCRIPTION OF EMBODIMENTS

A semiconductor manufacturing apparatus, a method of manufacturing a semiconductor apparatus, and a semiconductor apparatus according to the embodiments of the present disclosure will be described with reference to the drawings. The same reference numerals and signs are added to the same or corresponding components. Repetitive descriptions of the components are sometimes omitted.

### First Embodiment

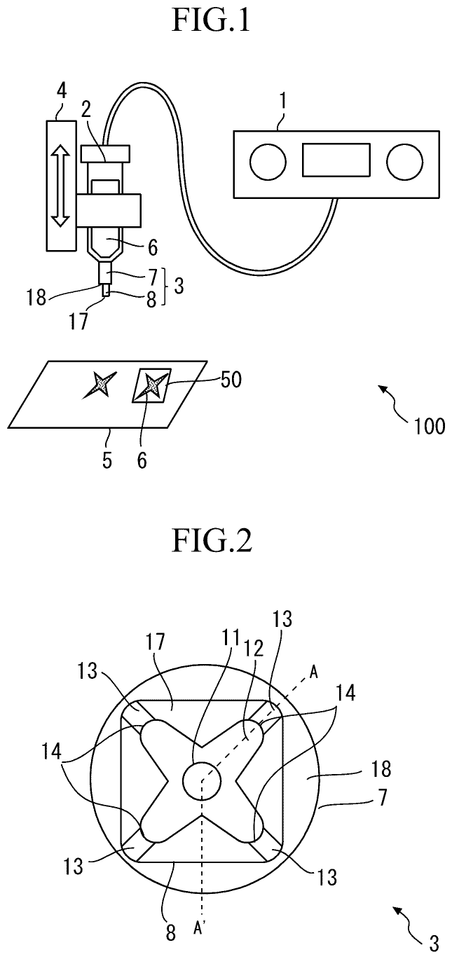

FIG. 1 is a diagram illustrating a semiconductor manufacturing apparatus 100 according to a first embodiment of the present disclosure. The semiconductor manufacturing apparatus 100 includes a dispenser 1, a syringe 2 that stores resin paste 6, a nozzle 3 connected to the syringe 2, and a lift 4.

The nozzle 3 discharges the filled resin paste 6 from the syringe 2. The nozzle 3 includes a base 7 and a tip 8 formed in the center of the base 7. A cross groove 12 is provided on a bottom surface 17 of the tip 8. A detailed configuration of the nozzle 3 is described below.

The dispenser 1 is a discharge device of a gas pressure or air pressure type that fills, via a supply hole 11, in the cross groove 12, the resin paste 6 stored in the syringe 2.

The lift 4 automatically or manually lifts and lowers the syringe 2 and the nozzle 3.

A method of bonding a semiconductor device 50 using the semiconductor manufacturing apparatus 100 of the present disclosure is as described below. First, the bottom surface 17 of the tip 8 is brought into contact with an application target object such as a die pad 5 by the lift 4. Further, the resin paste 6 is filled in the cross groove 12 from the supply hole 11 by the dispenser 1. Further, the nozzle 3 is separated from the application target object by the lift 4. Consequently, the resin paste 6 having a cross shape is applied to the application target object. Further, the semiconductor device 50, which is a quadrangular shape in plan view, is bonded such that the vertexes of a quadrangle formed by the semiconductor device 50 and the ends of a cross of the resin paste 6 discharged in the cross shape coincide. This makes it possible to bond the semiconductor device 50.

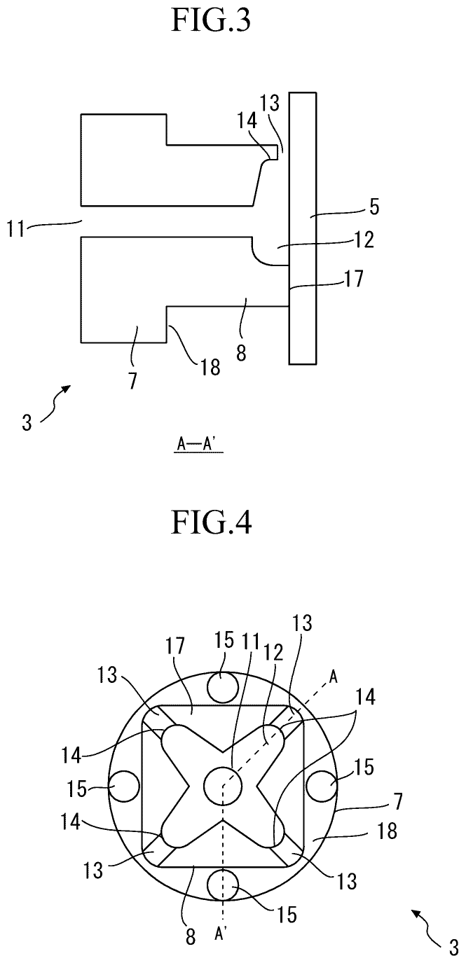

FIG. 2 is a diagram illustrating the bottom surface 17 of the tip 8 of the nozzle 3 according to the first embodiment of the present disclosure. FIG. 3 is an A-A′ sectional view of the nozzle 3 illustrated in FIG. 2. Note that, in order to describe a state in which the bottom surface 17 is set in contact with the die pad 5, the die pad 5 not illustrated in FIG. 2 is illustrated in FIG. 3.

A bottom surface 18 of the base 7 is circular as illustrated in FIG. 2. The bottom surface 17 of the tip 8 is a square, the corners of which are round-chamfered.

The supply hole 11 is provided in the center of the cross groove 12 on the bottom surface 17 of the tip 8 and communicates with the syringe 2 through the tip 8 and the base 7.

The size of the cross groove 12 in plan view is the same degree as the size in plan view of the semiconductor device 50 bonded in a later step. The cross groove 12 is formed on the diagonal lines of the square formed by the bottom surface 17 of the tip 8. The cross groove 12 is narrowed from the center toward the ends. This makes it possible to spread, to ends 14, the resin paste 6 supplied from the supply hole 11 without allowing the resin paste 6 to ooze.

Exhaust grooves 13 extend, on the bottom surface 17 of the tip 8, from the ends 14 of the cross groove 12 in directions in which the cross groove 12 is extended and extend to the outside of the bottom surface 17. That is, the exhaust grooves 13 are present on diagonal lines of the square formed by the bottom surface 17 of the tip 8. The exhaust grooves 13 are grooves that are narrower and shallower than the cross groove 12.

By providing the exhaust grooves 13, as illustrated in FIG. 3, even in a state in which the bottom surface 17 of the tip 8 is in contact with the die pad 5, it is possible to form, between the bottom surface 17 and the die pad 5, a gap for allowing air to escape.

Since the exhaust grooves 13 are shallower than the cross groove 12, the resin paste 6 filled in the cross groove 12 does not intrude into the exhaust grooves 13. That is, in this embodiment, it is possible to allow only air from the supply hole 11 to escape to the outside via the exhaust grooves 13 while filling the resin paste 6 in the cross groove 12. Therefore, it is possible to prevent the resin paste 6 from oozing to the outside from the ends 14 of the cross groove 12 together with air as in the related art. Further, it is possible to suppress occurrence of an air trap (air accumulation) in the cross groove 12 and prevent occurrence of air bubbles in the resin paste 6. As a result, it is possible to spread the resin paste 6 in a quadrangular shape.

Note that, as described above, on the bottom surface 17 of the tip 8, the corners pierced through by the exhaust grooves 13 are round-chamfered. Here, note that, if the corners are not chamfered, metal powder deriving from the die pad 5 can be caused by the sharp corners and the die pad 5 coming into contact. In this case, there is a concern about a bonding failure caused by the metal powder adhering to the resin paste 6 in the cross groove 12 via the exhaust grooves 13. In this embodiment, the occurrence of the metal powder and occurrence of the bonding failure are prevented by round-chamfering the corners.

As described above, in this embodiment, the cross groove 12 and the exhaust grooves 13 extending from the ends 14 of the cross groove 12 to the outside of the bottom surface 17 are formed on the bottom surface 17 of the nozzle 3. The exhaust grooves 13 are the grooves narrower and shallower than the cross groove 12. This makes it possible to allow only air from the supply hole 11 to escape to the outside of the nozzle 3 via the exhaust grooves 13 while filling the resin paste 6 in the cross groove 12. This makes it possible to provide a semiconductor manufacturing apparatus and a method of manufacturing a semiconductor apparatus that make it possible to spread resin paste in a quadrangular shape.

### Modification of the First Embodiment

Note that, in the above description, it is described that the bottom surface 17 of the tip 8 is the square, the corners of which are round-chamfered. However, the shape of the bottom surface 17 is not limited if the cross groove 12 and the exhaust grooves 13 described above are formed on the bottom surface 17. The shape may be, for example, a circle. The lengths of the exhaust grooves 13 extending from the ends 14 of the cross groove 12 to the outside of the bottom surface 17 may be different from one another depending on the shape of the bottom surface 17. Even in that case, the same effects as the effects described above can be obtained.

### Second Embodiment

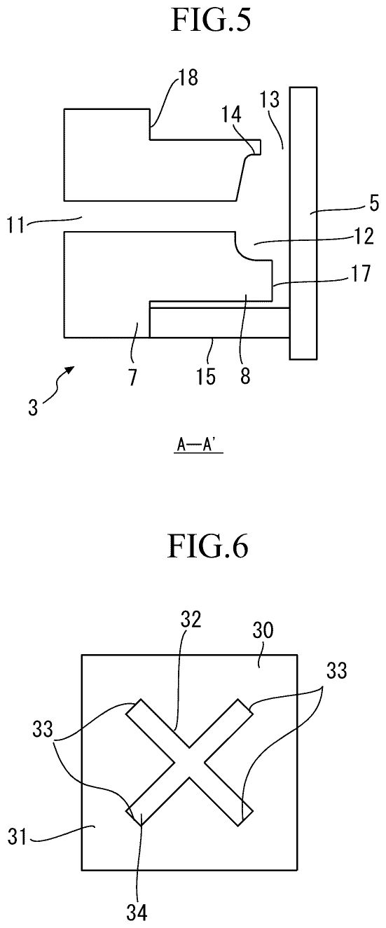

In this embodiment, pins 15 are disposed in the periphery of the bottom surface 17. Note that, in the following description, changes from the first embodiment are described. FIG. 4 is a diagram illustrating the bottom surface of the nozzle 3 of the semiconductor manufacturing apparatus 100 according to a second embodiment of the present disclosure. FIG. 5 is an A-A′ sectional view of the nozzle 3 illustrated in FIG. 4. Note that, in FIG. 5, the die pad 5 not illustrated in FIG. 4 is illustrated.

The pins 15 higher than the tip 8 by 40 to 100 μm are disposed on the bottom surface 18 of the base 7. Note that, here, the pins 15 are disposed in four directions of the tip 8. However, the number of pins 15 may be one.

By disposing one or more pins 15, as illustrated in FIG. 5, the bottom surface 17 of the tip 8 and the die pad 5 do not come into contact and a gap corresponding to the height of the pins 15 is formed between the bottom surface 17 and the die pad 5. The size of the gap is 40 to 100 μm at most. Therefore, a part of the resin paste 6 discharged from the nozzle 3 in this state is adsorbed by the die pad 5 and the remainder is adsorbed to the nozzle 3 side. It is possible to reduce a discharge time by using a phenomenon of adsorbing the resin paste 6 to the nozzle 3 side.

As described above, in the semiconductor manufacturing apparatus 100 in this embodiment, it is also possible to reduce the discharge time in addition to the effects described in the first embodiment.

### Modification of the Second Embodiment

Note that, in the above description, it is described that the pins 15 having a bar shape are disposed on the bottom surface 18 of the base 7. However, the shape and a disposition part of the pins 15 are not limited to the above. For example, L-shaped pins may be disposed on the sides of the tip 8 and projected from the bottom surface 17. Alternatively, pins may be disposed on the bottom surface 17 itself of the tip 8 or may adopt another configuration. In that case, the same effects as the effects described above can be obtained.

### Third Embodiment

In the embodiments described above, a technique of spreading the resin paste 6 in a quadrangular shape by devising the nozzle 3 of the semiconductor manufacturing apparatus 100 is described. On the other hand, in this embodiment, a technique for spreading the resin paste 6 in a quadrangular shape by devising a die pad of a semiconductor apparatus is described.

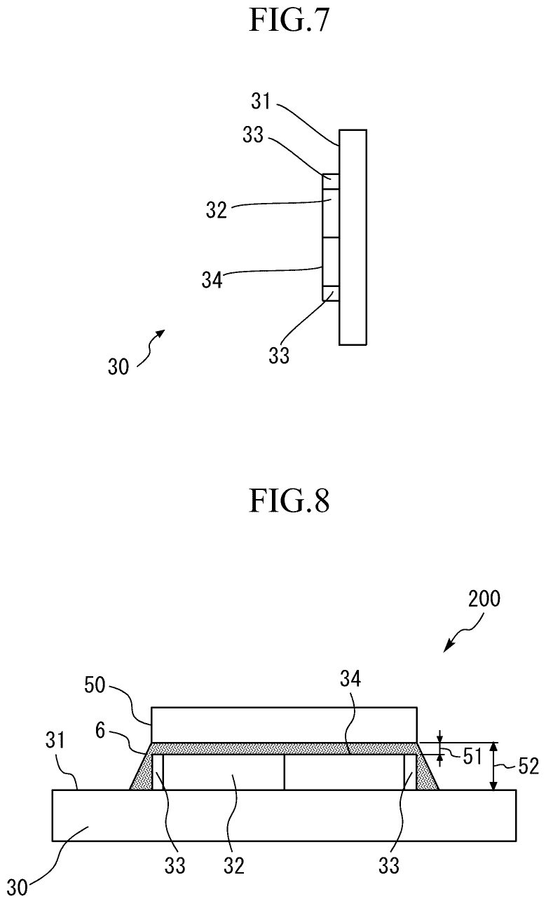

FIG. 6 is a top view of a die pad 30 according to a third embodiment of the present disclosure. FIG. 7 is a side view of the die pad 30 illustrated in FIG. 6. The die pad 30 includes a cross-shaped block 32 on an upper surface 31. The size of the block 32 in plan view is the same degree as the size in plan view of the semiconductor device 50 bonded in a later step.

FIG. 8 is a side view of a semiconductor apparatus 200 according to the third embodiment of the present disclosure. The semiconductor apparatus 200 includes the die pad 30 and the semiconductor device 50 bonded to the block 32 of the die pad 30 by the resin paste 6. The semiconductor device 50 is a quadrangle in plan view and is bonded such that the vertexes of the quadrangle and ends 33 of a cross of the block 32 coincide.

It is seen from FIG. 8 that a first gap 51 formed by an upper surface 34 of the block 32 and the semiconductor device 50 is narrower than a second gap 52 formed by the upper surface 31 of the die pad 30 and the semiconductor device 50. In manufacturing the semiconductor apparatus 200, the resin paste 6 is discharged to near the center of the cross-shaped block 32 and the semiconductor device 50 is placed on the resin paste 6. Since the first gap 51 is narrower than the second gap 52, the resin paste 6 selectively infiltrates into the first gap 51. More specifically, although the resin paste 6 isotropically spreads via the second gap 52 as well, the resin paste 6 spreads toward the ends 33 of the block 32 via the first gap 51 faster than spreading via the second gap 52. As a result, it is possible to spread the resin paste 6 in a quadrangular shape.

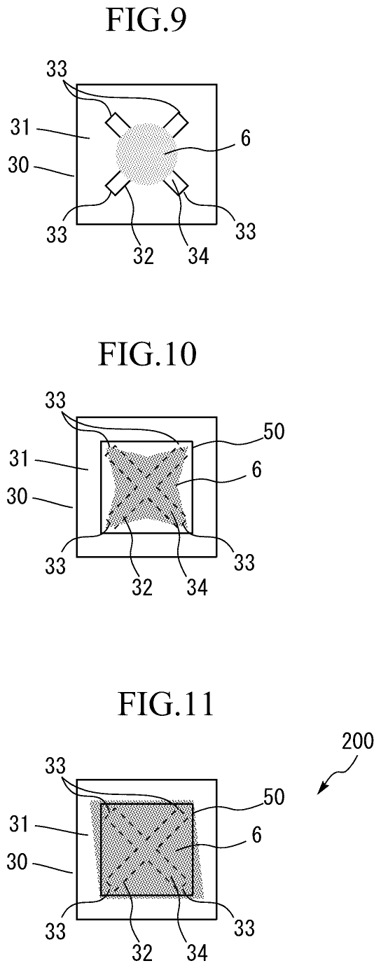

FIGS. 9 to 11 are diagrams illustrating a method of manufacturing the semiconductor apparatus 200 according to the third embodiment of the present disclosure. Here, a top view of the semiconductor apparatus 200 is illustrated. First, as illustrated in FIG. 9, the resin paste 6 is discharged to a range including the center of the cross of the block 32 of the die pad 30 and not including the ends 33.

Subsequently, as illustrated in FIG. 10, the semiconductor device 50, which is a quadrangle in plan view, is placed on the upper surface 34 of the block 32 to bond the die pad 30 and the semiconductor device 50 with the resin paste 6. At this time, the die pad 30 and the semiconductor device 50 are bonded such that the vertexes of the quadrangle formed by the semiconductor device 50 and the ends 33 of the block 32 coincide. This makes it possible to use the selective infiltration phenomenon of the resin paste 6 described above. As a result, the semiconductor apparatus 200 on which the resin paste 6 is spread in a quadrangular shape as illustrated in FIG. 11 is obtained.

As described above, in this embodiment, the cross-shaped block 32 is formed on the upper surface 31 of the die pad 30. By discharging the resin paste 6 to the range including the center of the block 32 and not including the ends 33 and placing the semiconductor device 50 on the resin paste 6, it is possible to selectively infiltrate the resin paste 6 into the gap formed by the upper surface 34 of the block 32 and the semiconductor device 50. This makes it possible to provide the semiconductor apparatus 200 and the method of manufacturing the semiconductor apparatus 200 that make it possible to spread the resin paste 6 in a quadrangular shape.

### Fourth Embodiment

In this embodiment as well, a technique for spreading the resin paste 6 in a quadrangular shape by devising the shape of a die pad is described.

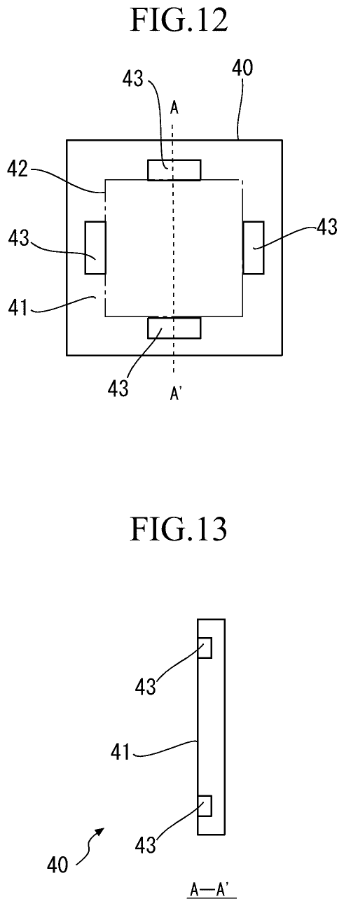

FIG. 12 is a top view of a die pad 40 according to a fourth embodiment of the present disclosure. FIG. 13 is an A-A′ sectional view of the die pad 40 illustrated in FIG. 12. The die pad 40 includes four grooves 43 extending along the sides of a square 42 on an upper surface 41. Note that the square 42 illustrated in FIG. 12 is an imaginary figure provided for description. The square 42 is not formed on the upper surface of the actual die pad 40. Note that the square 42 formed by four grooves 43 in plan view is equivalent to the size in plan view of the semiconductor device 50 bonded in a later process.

In plan view, each of the four grooves 43 is present in the center of the side of the square 42 but is absent at both the ends of the side. Specifically, the length of the four grooves 43 is desirably approximately half of the side of the square 42.

The four grooves 43 are desirably formed in equal positions from both the ends.

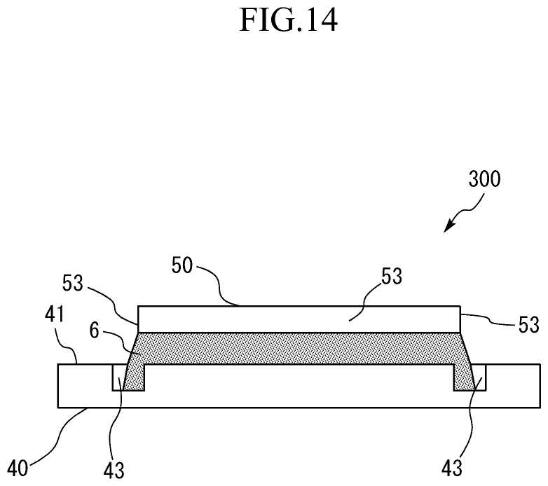

FIG. 14 is a side view of a semiconductor apparatus 300 according to the fourth embodiment of the present disclosure. The semiconductor apparatus 300 includes the semiconductor device 50, four sides 53 of which form a quadrangle in plan view, and the die pad 40, to the upper surface 41 of which the semiconductor device 50 is bonded by the resin paste 6. The semiconductor device 50 is bonded such that the vertexes of the quadrangle formed by the semiconductor device 50 and the vertexes of the square 42 formed by the four grooves 43 coincide.

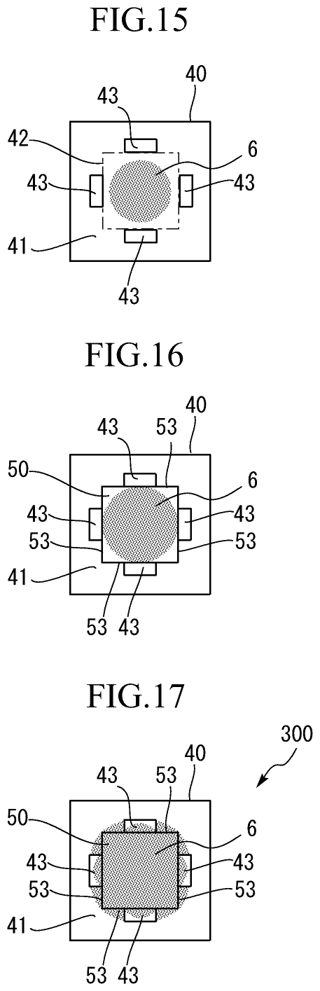

FIGS. 15 to 17 are diagrams illustrating a method of manufacturing the semiconductor apparatus 300 according to the fourth embodiment of the present disclosure. First, as illustrated in FIG. 15, the resin paste 6 is discharged to a range including the center of the square 42 formed by the grooves 43 of the die pad 40 and not including the grooves 43.

Subsequently, the semiconductor device 50, which is a quadrangle in plan view, is placed on the discharged resin paste 6 to bond the die pad 40 and the semiconductor device 50 with the resin paste 6. At this time, the die pad 40 and the semiconductor device 50 are bonded such that the direction of the quadrangle formed by the semiconductor device 50 and the direction of the square 42 formed by the grooves 43 coincide. Since the resin paste 6 isotropically spreads, as illustrated in FIG. 16, in the square 42, the resin paste 6 reaches the grooves 43 earliest. However, the reached resin paste 6 is poured into the grooves 43. A further advance of the resin paste 6 can be delayed. On the other hand, the grooves 43 are absent in an advancing direction of the resin paste 6 toward the vertexes of the square 42. As a result, as illustrated in FIG. 17, the semiconductor apparatus 300 in which the resin paste 6 is spread in a quadrangular shape is obtained.

As described above, the square 42 formed by the four grooves 43 formed on the upper surface 41 of the die pad 40 is equivalent to the size in plan view of the semiconductor device 50. Therefore, in plan view of the semiconductor apparatus 300 illustrated in FIG. 17, the four grooves 43 extend along the respective sides 53 of the semiconductor device 50. Further, in plan view, the grooves 43 are present in the centers of the sides 53 but are absent at both the ends of the sides 53 and are formed in equal positions from both the ends of the sides 53. Note that, in order to pour only the resin paste 6 spreading toward the centers of the sides of the square 42, the length of the grooves 43 is desirably half of the length of the sides 53. The four grooves 43 are desirably formed in equal positions from both the ends of the sides 53.

As described above, the die pad 40 in this embodiment includes the four grooves 43 extending along the respective sides 53 of the semiconductor device 50 in plan view. The grooves 43 are configured to be present in the centers of the sides 53 but absent at both the ends of the sides 53 in plan view. By forming the grooves 43, it is possible to delay an advance of the resin paste 6 in the directions of the grooves 43. This makes it possible to provide the semiconductor apparatus 300 and the method of manufacturing the semiconductor apparatus 300 that make it possible to spread the resin paste 6 in a quadrangular shape.

Note that the present disclosure is not limited to the embodiments described above. At an implementation stage, the present disclosure can be variously modified without departing from the gist of the present disclosure. The embodiments may be implemented in combination as appropriate. In that case, effects of the combination can be obtained.

Note that it is assumed that the quadrangle in the present disclosure includes a square and a substantial square.

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2023-183559, filed on Oct. 25, 2023 including specification, claims, drawings and summary, on which the convention priority of the present application is based, is incorporated herein by reference in its entirety.

1. A semiconductor manufacturing apparatus comprising:
a nozzle including a cross groove provided on a bottom surface, a supply hole provided in a center of the cross groove, and exhaust grooves that extend from ends of the cross groove to an outside of the bottom surface on the bottom surface and are shallower than the cross groove;
a syringe configured to store resin paste and connected to the nozzle; and
a dispenser configured to fill, in the cross groove, the resin paste in the syringe via the supply hole with a gas pressure or an air pressure.

2. The semiconductor manufacturing apparatus according to claim 1, wherein
the bottom surface is a quadrangle, corners of which are round-chamfered, and
the cross groove and the exhaust grooves are formed on diagonal lines of the quadrangle.

3. The semiconductor manufacturing apparatus according to claim 1, wherein the nozzle includes one or more pins projecting from a periphery of the bottom surface or from the bottom surface, the pins projecting by 40 to 100 μm from the bottom surface.

4. The semiconductor manufacturing apparatus according to claim 2, wherein the nozzle includes one or more pins projecting from a periphery of the bottom surface or from the bottom surface, the pins projecting by 40 to 100 μm from the bottom surface.

5. A method of manufacturing a semiconductor apparatus comprising:
a step of bringing a bottom surface of a nozzle into contact with an application target object, the nozzle including a cross groove provided on the bottom surface, a supply hole provided in a center of the cross groove, and exhaust grooves that extend from ends of the cross groove to an outside of the bottom surface on the bottom surface and are shallower than the cross groove;
a step of filling resin paste in the cross groove from the supply hole with a gas pressure or an air pressure;
a step of separating the nozzle from the application target object and discharging the resin paste having a cross shape to the application target object; and
a step of bonding a semiconductor device, which is a quadrangle in plan view, such that vertexes of the quadrangle and ends of a cross of the resin paste discharged in the cross shape coincide.

6. A method of manufacturing a semiconductor apparatus comprising:
a step of discharging resin paste to a range including a center of a cross-shaped block formed on a die pad and not including ends of the block; and
a step of placing a semiconductor device, which is a quadrangle in plan view, on an upper surface of the block such that vertexes of the quadrangle and ends of a cross of the block coincide to bond the die pad and the semiconductor device with the resin paste.

7. A method of manufacturing a semiconductor apparatus comprising:
a step of forming a die pad including, on an upper surface, four grooves extending along respective sides of a quadrangle;
a step of discharging resin paste to a range including a center of the quadrangle formed by the four grooves and not including the four grooves; and
a step of placing a semiconductor device, which is a quadrangle in plan view, on the upper surface of the die pad such that vertexes of the quadrangle formed by the semiconductor device and vertexes of the quadrangle formed by the four grooves coincide to bond the die pad and the semiconductor device with the resin paste, wherein
in plan view, the four grooves are present in centers of sides of the bonded semiconductor device and are absent at both ends of the sides of the semiconductor device.

8. A semiconductor apparatus comprising:
a die pad including a cross-shaped block on an upper surface; and
a semiconductor device bonded to the block by resin paste, wherein
the semiconductor device is a quadrangle in plan view and is bonded such that vertexes of the quadrangle of the semiconductor device and ends of a cross of the block coincide.

9. A semiconductor apparatus comprising:
a die pad; and
a semiconductor device bonded to the die pad by resin paste, four sides of the semiconductor device forming a quadrangle in plan view, wherein
the die pad includes, on a surface to which the semiconductor device is bonded, four grooves extending along the respective sides, and
the grooves are present in centers of the sides in plan view and are absent at both ends of the sides.

10. The semiconductor apparatus according to claim 9, wherein
length of the grooves is half of length of the sides, and
the grooves are formed in equal positions from both ends of the sides.
